(19) United States
(12) Patent Application Publication
(10) Pub. No.: US 2025/0192108 A1
(43) Pub. Date: Jun. 12, 2025

(54) SEMICONDUCTOR PACKAGE AND METHOD OF MANUFACTURING SEMICONDUCTOR PACKAGE

(71) Applicant: SAMSUNG ELECTRONICS CO., LTD., Suwon-si (KR)

(72) Inventors: Haseob SEONG, Suwon-si (KR); Dawoon JUNG, Suwon-si (KR)

(73) Assignee: SAMSUNG ELECTRONICS CO., LTD., Suwon-si (KR)

(21) Appl. No.: 18/733,089

(22) Filed: Jun. 4, 2024

(30) Foreign Application Priority Data
Dec. 12, 2023 (KR) 10-2023-0179359

(51) Int. Cl. H01L 25/065; H01L 23/00; H01L 23/48; H01L 23/498

(52) U.S. Cl. CPC H01L 25/0657; H01L 23/481; H01L 24/08; H01L 23/49816; H01L 2224/08145; H01L 2224/08225; H01L 2225/06548; H01L 2225/06568; H01L 2225/06572

(57) ABSTRACT

A semiconductor package includes an interconnection chip between a first chip stack and a second chip stack, the interconnection chip including interconnection vias electrically connecting the first through-vias and the second through-vias to each other. The interconnection chip has a first surface in contact with the first chip stack, a second surface in contact with the second chip stack, and a third surface between the first surface and the second surface. The third surface of the interconnection chip includes a first portion extending from the first surface of the interconnection chip at a first inclination, and a second portion extending from the first portion to the second surface of the interconnection chip at a second inclination lower than the first inclination.

### CROSS-REFERENCE TO RELATED APPLICATION(S)

This application claims benefit of priority to Korean Patent Application No. 10-2023-0179359 filed on Dec. 12, 2023 in the Korean Intellectual Property Office, the disclosure of which is incorporated herein by reference in its entirety.

### BACKGROUND

### 1. Field

The embodiments of the present disclosure relate to a semiconductor package and a method of manufacturing the same.

### 2. Description of Related Art

Due to the rapid developments of the electronics industry and demands of users, electronic devices are becoming smaller and lighter. Semiconductor devices, installed in such electronic devices, require implementation of high performance and large capacity, together with miniaturization. In order to implement high performance and large capacity, together with miniaturization, a semiconductor package has been developed to interconnect semiconductor chips stacked in a vertical direction using a through-electrode (e.g.,, a through-silicon via). However, as the number of chips in such packages increases, surface topology properties may be upwardly degraded resulting in low bonding quality.

### SUMMARY

An aspect of the embodiments of the present disclosure provide a semiconductor package having improved reliability.

According to an aspect of the disclosure, a semiconductor package comprises a base chip comprising first connection terminals and second connection terminals opposite to each other, and through-electrodes electrically connecting the first connection terminals and the second connection terminals to each other; a first chip stack stacked on the base chip in a first direction, the first chip stack comprising a plurality of first semiconductor chips comprising a first set of pads and a second set of upper pads, opposite to each other, and first through-vias electrically connecting the first set of pads and the second set of pads to each other; a second chip stack stacked on the first chip stack in the first direction, the second chip stack comprising a plurality of second semiconductor chips comprising a third set of pads and a fourth set of pads, opposite to each other, and second through-vias electrically connecting the third set of pads and the fourth set of pads to each other; an interconnection chip between the first chip stack and the second chip stack, the interconnection chip comprising interconnection vias electrically connecting the first through-vias and the second through-vias to each other; a mold layer covering at least a portion of each of the first chip stack, the second chip stack, and the interconnection chip, on the base chip; and a plurality of connection bumps below the base chip, the plurality of connection bumps electrically connected to the first connection terminals, wherein the first set of pads of each of the plurality of first semiconductor chips are in contact with the second connection terminals of the base chip adjacent thereto in the first direction, and the second set of pads of each of the plurality of first semiconductor chips adjacent thereto in the first direction, the fourth set of pads of each of the plurality of second semiconductor chips are in contact with the third set of pads of each of the plurality of second semiconductor chips adjacent thereto in the first direction, the interconnection chip has a first surface in contact with the first chip stack, a second surface in contact with the second chip stack, and a third surface between the first surface and the second surface, and the third surface of the interconnection chip comprises a first portion extending from the first surface of the interconnection chip at a first inclination, and a second portion extending from the first portion to the second surface of the interconnection chip at a second inclination lower than the first inclination.

According to an aspect of the disclosure, a semiconductor package comprises: a base chip comprising through-electrodes; a first chip stack stacked on the base chip in a first direction, the first chip stack comprising a plurality of first semiconductor chips comprising first through-vias electrically connected to the through-electrodes in the first direction, the first through-vias electrically connected to each other in the first direction; a second chip stack stacked on the first chip stack in the first direction, the second chip stack comprising a plurality of second semiconductor chips comprising second through-vias electrically connected to each other in the first direction; an interconnection chip between the first chip stack and the second chip stack, the interconnection chip comprising interconnection vias electrically connecting the first through-vias and the second through-vias to each other; and a mold layer covering a surface of the first chip stack extending in the first direction, a surface of the second chip stack extending in the first direction, and a surface of the interconnection chip extending in the first direction, wherein the interconnection chip includes a first region overlapping the second chip stack in the first direction, and a second region extending from the first region and overlapping the mold layer and the first chip stack in the first direction.

According to an aspect of the disclosure, a semiconductor package comprises: a base chip comprising through-electrodes; a plurality of first semiconductor chips stacked on the base chip in a first direction, the plurality of first semiconductor chips comprising first through-vias electrically connected to the through-electrodes in the first direction, the first through-vias electrically connected to each other in the first direction; a plurality of second semiconductor chips stacked on the plurality of first semiconductor chips in the first direction, the plurality of second semiconductor chips comprising second through-vias electrically connected to each other in the first direction; and an interconnection chip between a top first semiconductor chip among the plurality of first semiconductor chips, and a bottom second semiconductor chip among the plurality of second semiconductor chips, the interconnection chip comprising interconnection vias electrically connecting the first through-vias and the second through-vias to each other, wherein a thickness of the interconnection chip in the first direction is less than a thickness of each of the plurality of first semiconductor chips and a thickness of each of the plurality of second semiconductor chips, the interconnection chip has a first surface in contact with the top first semiconductor chip, and a second surface in contact with the bottom second semiconductor chip, the first surface of the interconnection chip is a wave surface having varying heights, and the second surface of the interconnection chip is a flat surface.

According to an aspect of the disclosure, a method of manufacturing a semiconductor package comprises forming first chip stacks comprising a plurality of first semiconductor chips on a semiconductor wafer; attaching interconnection chips to the first chip stacks, respectively; applying a planarization process to the interconnection chips; and forming second chip stacks comprising a plurality of second semiconductor chips on the planarized interconnection chips, wherein a width of each of the second chip stacks is narrower than a width of each of the corresponding interconnection chips.

### BRIEF DESCRIPTION OF DRAWINGS

The above and other aspects, features, and advantages of the present embodiments will be more clearly understood from the following detailed description, taken in conjunction with the accompanying drawings, in which:

FIG. 1A is a plan view of a semiconductor package according to an example embodiment of the present disclosure, and FIG. 1B is a cross-sectional view taken along line I-I′ of FIG. 1A;

FIG. 2A is a partially enlarged view of region “A” of FIG. 1A, and FIGS. 2B to 2D are example modifications of FIG. 2A;

FIG. 3A is a partially enlarged view of region “B” of FIG. 1A, and FIGS. 3B to 3C are example modifications of FIG. 3A;

FIG. 4 is a cross-sectional view of a semiconductor package according to an example embodiment;

FIG. 5 is a cross-sectional view of a semiconductor package according to an example embodiment;

FIG. 6 is a cross-sectional view of a semiconductor package according to an example embodiment;

FIG. 7A is a plan view of a semiconductor package according to an example embodiment of the present disclosure, and FIG. 7B is a cross-sectional view taken along line II-II′ of FIG. 7A;

FIGS. 8A to 11B are diagrams illustrating a process of manufacturing a semiconductor package according to an example embodiment; and

FIGS. 12A and 12B are graphs illustrating surface topology of an interconnection chip before and after a planarization process is performed.

### DETAILED DESCRIPTION

Hereinafter, preferred example embodiments will be described in detail. Unless otherwise described, the terms such as “upper,” “upper portion,” “upper surface,” “lower,” “lower portion,” “lower surface,” and “side surface” are based on the drawings, and may vary depending on a direction in which a component is actually arranged.

In addition, ordinal numbers such as “first,” “second,” “third,” and the like may be used as labels for specific devices, operations, directions, and the like, to distinguish various devices, steps, directions, and the like from one another. A term, not described in the specification using “first,” “second,” and the like, may still be referred to as “first” or “second” in the claims. In addition, a term referenced by a particular ordinal number (for example, “first” in a particular claim) may be described elsewhere with a different ordinal number (for example, “second” in the specification or another claim).

The specification uses the terms of degree including “substantially” or “about.” In one or more examples, when specifying that a parameter X may be substantially the same as parameter Y, the term “substantially” may be understood as X being within 10% of Y. In one or more examples, when specifying that a parameter is about X, the term “about” may be understood as being within 10% of X.

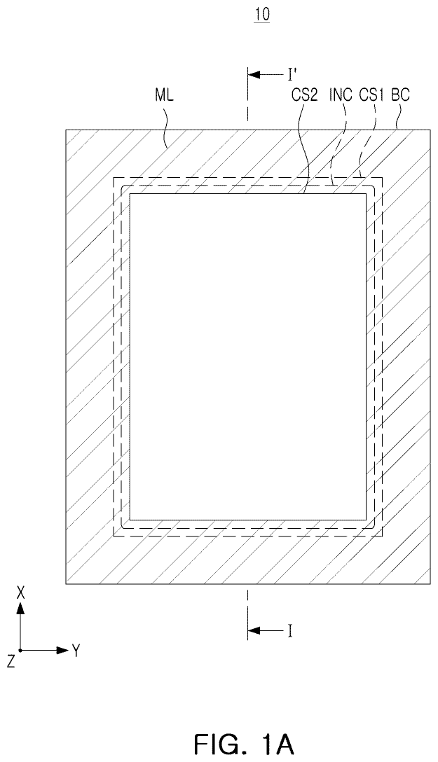

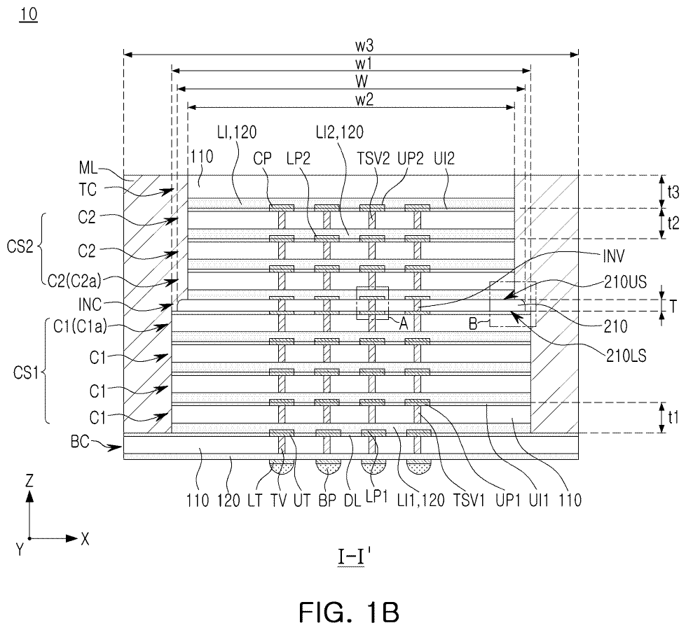

FIG. 1A is a plan view of a semiconductor package 10 according to an example embodiment of the present disclosure, and FIG. 1B is a cross-sectional view taken along line I-I′ of FIG. 1A.

Referring to FIGS. 1A and 1B, the semiconductor package 10 according to the example embodiment may include a base chip BC, a plurality of chip stacks CS1 and CS2, and at least one interconnection chip INC. In some example embodiments, the semiconductor package 10 may further include a top semiconductor chip TC, a mold layer ML, and/or a plurality of connection bumps BP.

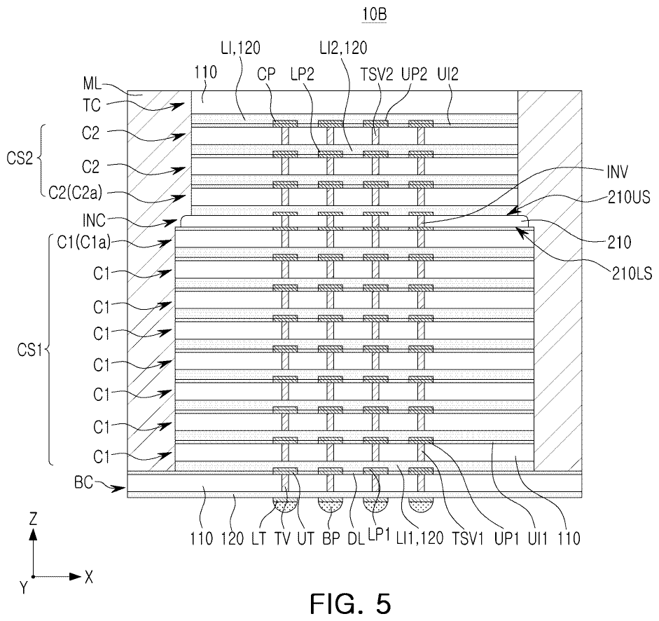

The plurality of chip stacks CS1 and CS2 may be sequentially disposed on the base chip BC. For example, the plurality of chip stacks CS1 and CS2 may include a first chip stack CS1 and a second chip stack CS2 stacked in a vertical direction (Z-direction). Each of the chip stacks CS1 and CS2 may include a plurality of semiconductor chips C1 and C2 stacked in the vertical direction (Z-direction). The first chip stack CS1 may include a plurality of first semiconductor chips C1 stacked on the base chip BC in a first direction (Z-direction). The second chip stack CS2 may include a plurality of second semiconductor chips C2 stacked on the interconnection chip INC in the first direction (Z-direction). In some example embodiments, the number of first semiconductor chips C1 and the number of second semiconductor chips C2 may be less than or greater than those illustrated in the drawings. For example, the first chip stack CS1 may include three or less or five or more (e.g.,, eight, twelve, or like) first semiconductor chips C1, and the second chip stack CS2 may include two or less or four or more second semiconductor chips C2. In addition, in the drawings, the number (e.g., four) of first semiconductor chips C1 is illustrated to be equal to the number (e.g., four) of second semiconductor chips C2 and the top semiconductor chip TC, but the present embodiments are not limited (see the example embodiment in FIG. 5).

The plurality of first semiconductor chips C1 may include first lower pads LP1 (e.g., first set of pads) and first upper pads UP1 (e.g., second set of pads) opposite to each other, and first through-vias TSV1 electrically connecting first lower pads LP1 and first upper pads UP1 to each other. The first through-vias TSV1 may be electrically connected to the through-electrodes TV in the first direction (Z-direction), and electrically connected to each other in the first direction (Z-direction).

The plurality of second semiconductor chips C2 may include second lower pads LP2 (e.g., third set of pads) and second upper pads UP2 (e.g., fourth set of pads) opposite to each other, and second through-vias TSV2 electrically connecting second lower pads LP2 and second upper pads UP2 to each other. The second through-vias TSV2 may be electrically connected to the first through-vias TSV1 in the first direction (Z-direction), and electrically connected to each other in the first direction (Z-direction).

In one or more examples, the top semiconductor chip TC may include connection pads CP electrically connected to the second through-vias TSV2 of the second top semiconductor chip C2. The connection pads CP may be understood as components having features the same as or similar to those of the lower pads LP to be described below. In some example embodiments, a thickness t3 of the top semiconductor chip TC may be greater than a thickness t1 of the first semiconductor chip C1 and a thickness t2 of the second semiconductor chip C2, but the present embodiments are not limited thereto.

In one or more examples, the plurality of first semiconductor chips C1, the plurality of second semiconductor chips C2, and the top semiconductor chip TC may include substantially the same or similar components. Thus, hereinafter, the same or similar components may be denoted by the same or similar terms and/or reference numerals. The plurality of first semiconductor chips C1, the plurality of second semiconductor chips C2, and the top semiconductor chip TC may be collectively referred to as “semiconductor chips C1, C2, and TC.” In one or more examples, the top semiconductor chip TC may be referred to as a third semiconductor chip.

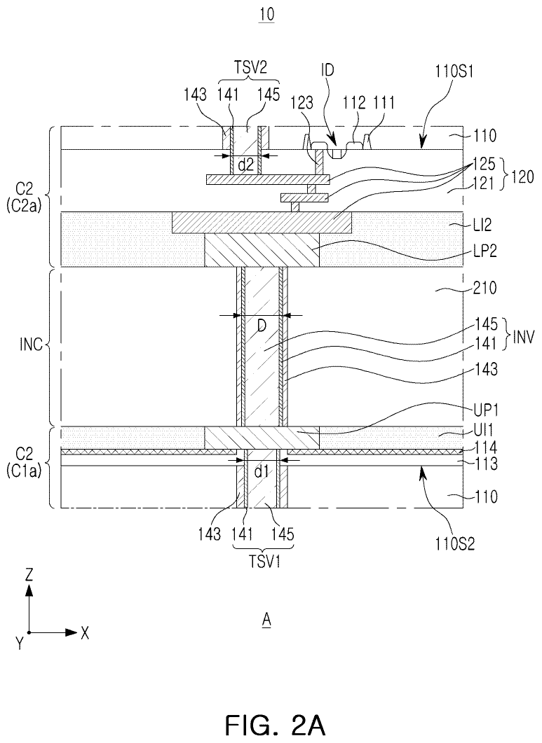

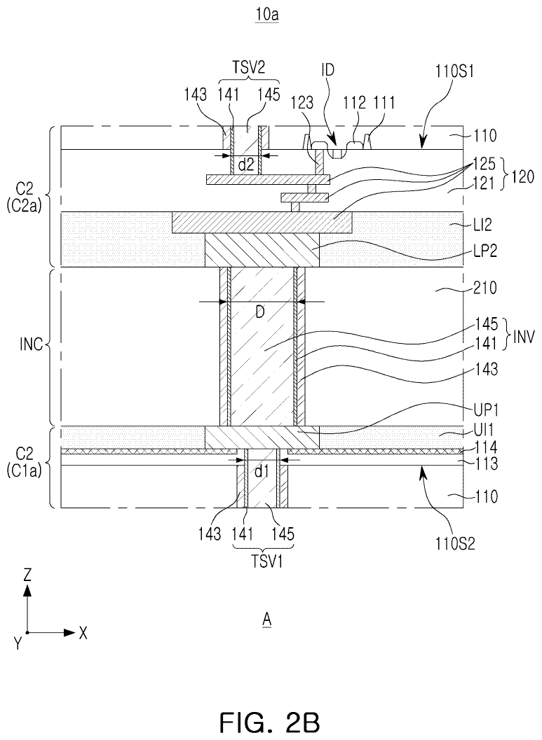

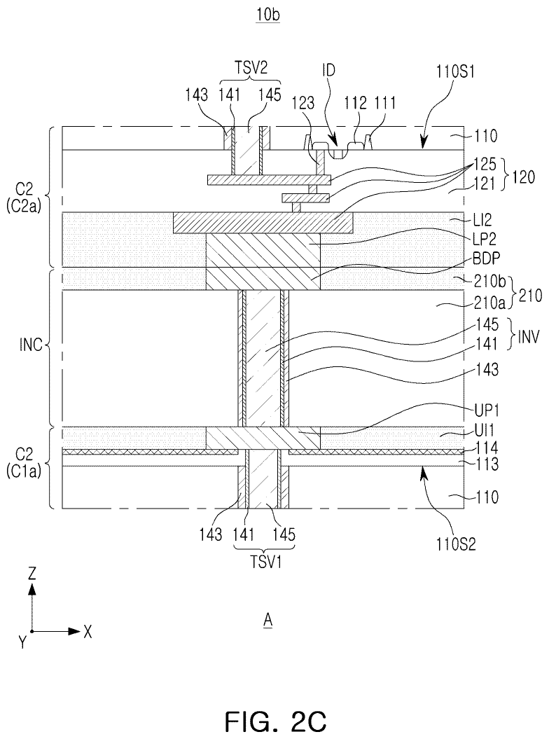

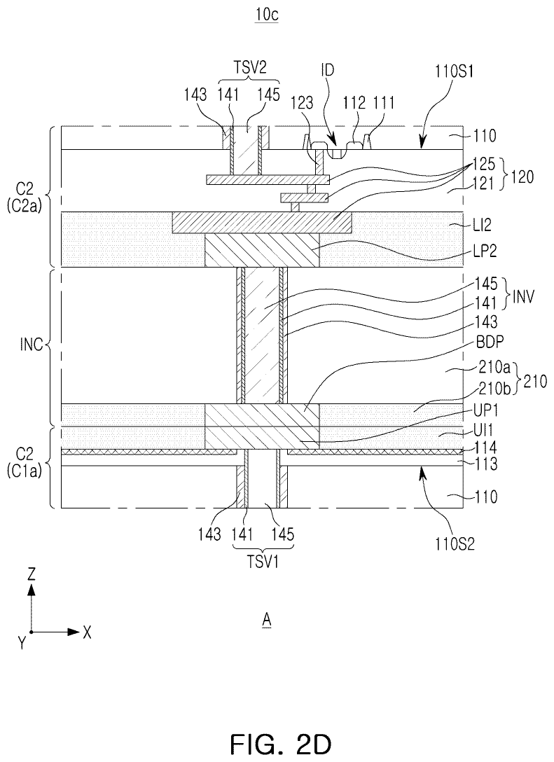

The semiconductor chips C1, C2, and TC may include a substrate 110, a circuit layer 120, a lower insulating layer LI, lower pads LP, an upper insulating layer UI, upper pads UP, and/or through-vias TSV. The top semiconductor chip TC may include only the substrate 110, the circuit layer 120, the third lower insulating layer LI, and the connection pads CP. The substrate 110, the circuit layer 120, and the like will be described in more detail with reference to FIG. 2A. In this specification, the lower insulating layer LI, the lower pads LP, the upper insulating layer UI, the upper pads UP, and/or the through-vias TSV may be understood to refer collectively to corresponding first and second components, respectively. For example, it may be understood that the lower insulating layer LI refers to both a first lower insulating layer LII (e.g., first insulating layer) and a second lower insulating layer LI2 (e.g., third insulating layer), and the through-vias TSV refer to both first through-vias TSV1 and second through-vias TSV2.

The at least one interconnection chip INC may be disposed between the plurality of chip stacks CS1 and CS2. For example, the interconnection chip INC may be disposed between the first chip stack CS1 and the second chip stack CS2. The interconnection chip INC may include interconnection vias INV electrically connecting the first chip stack CS1 and the second chip stack CS2 to each other. The interconnection vias INV may electrically connect the first through-vias TSV1 and the second through-vias TSV2 to each other.

In example embodiments, the plurality of first semiconductor chips C1, the plurality of second semiconductor chips C2, and the interconnection chip INC may be bonded and coupled to each other by inter-metal bonding and inter-dielectric bonding.

For example, each of the plurality of first semiconductor chips C1 may include a first lower insulating layer LI1 surrounding the first lower pads LP1, and a first upper insulating layer UI1 (e.g., second insulating layer) surrounding the first upper pads UP1. Each of the plurality of second semiconductor chips C2 may include the second lower insulating layer LI2 surrounding the second lower pads LP2, and a second upper insulating layer UI2 (e.g., fourth insulating layer) surrounding the second upper pads UP2. The interconnection chip INC may include a chip body 210 surrounding the interconnection vias INV, the chip body 210 defining a lower surface 210LS and an upper surface 210US.

The first lower insulating layer LI1 of each of the plurality of first semiconductor chips C1 may be in contact with a dielectric layer DL of the base chip BC adjacent thereto in the first direction (Z-direction), and the first upper insulating layer UI1 of each of the plurality of first semiconductor chips C1 adjacent thereto in the first direction (Z-direction). The second upper insulating layer UI2 of each of the plurality of second semiconductor chips C2 may be in contact with the second lower insulating layer LI2 of each of the plurality of second semiconductor chips C2 adjacent thereto in the first direction (Z-direction).

The first lower pads LP1 of each of the plurality of first semiconductor chips C1 may be in contact with upper connection terminals UT of the base chip BC adjacent thereto in the first direction (Z-direction), and the first upper pads UP1 of each of the plurality of first semiconductor chips C1 adjacent thereto in the first direction (Z-direction). The second upper pads UP2 of each of the plurality of second semiconductor chips C2 may be in contact with the second lower pads LP2 of each of the plurality of second semiconductor chips C2 adjacent thereto in the first direction (Z-direction).

In one or more examples, the first lower insulating layer LI1, the first upper insulating layer UI1, the second lower insulating layer LI2, and the second upper insulating layer UI2 may include at least one of silicon oxide (SiO) and silicon carbonitride (SiCN). The chip body 210 of the interconnection chip INC may include a material to which the first upper insulating layer UI1 and the second lower insulating layer LI2 may be bonded and coupled. For example, the chip body 210 of the interconnection chip INC may include a semiconductor material such as silicon (Si), germanium (Ge), or the like, but the present embodiments are not limited thereto.

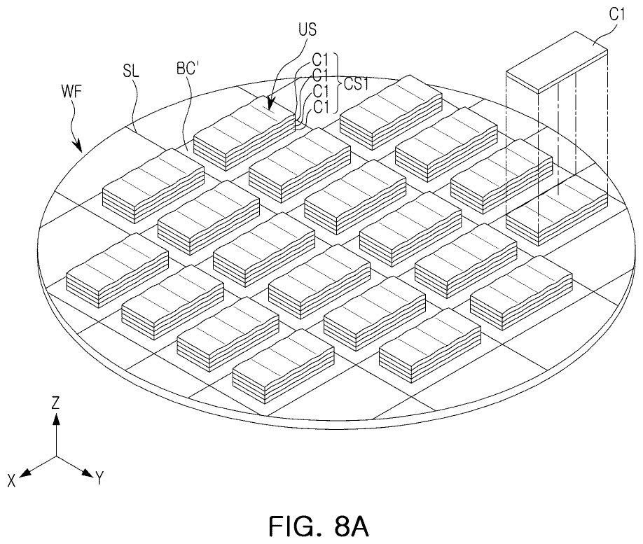

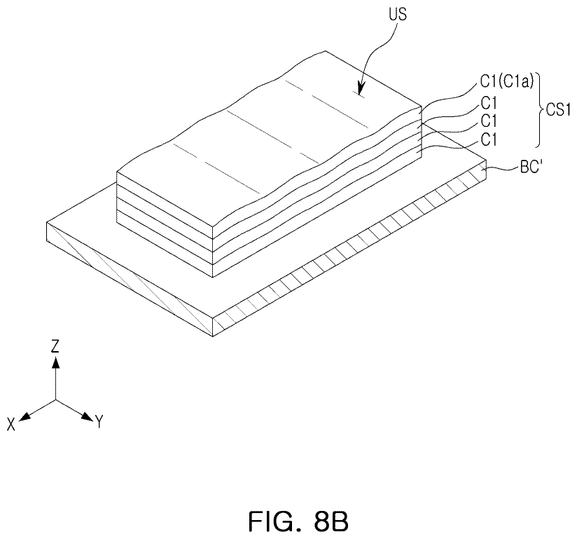

The interconnection chip INC may remove surface topology accumulated by the plurality of first semiconductor chips C1, thereby improving bonding quality and reliability of semiconductor chips additionally stacked. The interconnection chip INC may have a lower surface 210LS (e.g., first surface) in contact with a top first semiconductor chip C1a, among the plurality of first semiconductor chips C1, and an upper surface 210US (e.g., second surface) in contact with a bottom second semiconductor chip C2a, among the plurality of second semiconductor chips C2. The lower surface 210LS of the interconnection chip INC may be a wave surface in contact with an upper surface of the top first semiconductor chip C1a having the accumulated surface topology of the plurality of first semiconductor chips C1. In one or more examples, the upper surface 210US of the interconnection chip INC may be a flat surface or substantially flat surface to which a planarization process has been applied, which will be described in more detail with reference to FIGS. 8A to 12B.

In example embodiments, the upper surface 210US of the interconnection chip INC may have polished edges, and thus, some regions of the upper surface 210US of the interconnection chip INC may not provide a flat surface necessary for inter-dielectric bonding. Accordingly, the plurality of second semiconductor chips C2 may have a horizontal width, narrower than a horizontal width of the interconnection chip INC. For example, a first width w1 of the first chip stack CS1 in a second direction (X-direction) may be wider than a second width w2 of the second chip stack CS2 in the second direction (X-direction). A width W of the interconnection chip INC in the second direction (X-direction) may be equal to or narrower than the first width w1, and may be wider than the second width w2. A third width w3 of the base chip BC in the second direction (X-direction) may be wider than the first width w1, but the present embodiments are not limited thereto.

In example embodiments, a thickness of the interconnection chip INC may be less than a thickness of each of the first plurality of semiconductor chips C1 and the plurality of second semiconductor chips C2. For example, a thickness T from the lower surface 210LS to the upper surface 210US of the interconnection chip may be less than a thickness t1 of each of the plurality of first semiconductor chips C1 and a thickness t2 of each of the plurality of second semiconductor chips C2. The thickness T of the interconnection chip INC may be about 30 μm or less, for example, in a range of about 20 μm to about 30 μm, about 15 μm to about 25 μm, about 10 μm to about 20 μm, or the like, but the present inventive concept is not limited thereto.

In one or more examples, the base chip BC may be a buffer chip or control chip including multiple logic devices and/or memory devices. For example, the base chip BC may externally transmit signals from the first semiconductor chips C1, the second semiconductor chips C2, and the top semiconductor chip TC stacked thereon, and may also transmit external signals and power to the semiconductor chips C1 and C2. The semiconductor chips C1, C2, and TC may be memory chips including volatile memory devices such as DRAM and SRAM, or non-volatile memory devices such as PRAM, MRAM, FeRAM, and RRAM.

Components of the base chip BC may have features substantially the same as or similar to those of components of the semiconductor chips C1, C2, and TC. Thus, the same or similar components may be denoted by the same or similar terms and/or reference numerals, and repeated descriptions may be replaced with descriptions of corresponding components. For example, it may be understood that lower connection terminals LT (e.g., first connection terminals) and the upper connection terminals UT (e.g., second connection terminals) of the base chip BC correspond to the lower pads LP (e.g., first set of pads and third set of pads) and the upper pads UP (e.g., second set of pads and fourth set of pads) of the semiconductor chips C1, C2, and TC, the dielectric layer DL of the base chip BC corresponds to the lower insulating layer LI and the upper insulating layer UI of each of the semiconductor chips C1, C2, and TC, and the through-electrodes TV of the base chip BC TV correspond to the through-vias TSV of the semiconductor chips C1 and C2.

In one or more examples, the base chip BC may include lower connection terminals LT and upper connection terminals UT opposite to each other, and through-electrodes TV electrically connecting the lower connection terminals LT and the upper connection terminals UT to each other.

In one or more examples, the base chip BC may further include a dielectric layer DL surrounding the upper connection terminals UT. The upper connection terminals UT may be in direct contact with the first lower pads LP1 of the bottom first semiconductor chip C1 adjacent thereto in the vertical direction (Z-direction). The dielectric layer DL may be in direct contact with the first lower insulating layer LI1 (e.g., first insulating layer) of the bottom first semiconductor chip C1 adjacent thereto in the vertical direction (Z-direction).

In one or more examples, the base chip BC may be electrically connected to an external device (e.g., a main board) through a plurality of connection bumps BP. The plurality of connection bumps BP may be disposed below the base chip BC, and may be electrically connected to the lower connection terminals LT. The plurality of connection bumps BP may include, for example, tin (Sn), indium (In), bismuth (Bi), antimony (Sb), copper (Cu), silver (Ag), zinc (Zn), lead. (Pb) and/or alloys thereof. In some example embodiments, the plurality of connection bumps BP may have a combination of a conductive pillar and a solder ball.

The mold layer ML may cover at least a portion of each of the plurality of chip stacks CS1 and CS2, the at least one interconnection chip INC, and the top semiconductor chip TC, on the base chip BC. For example, the mold layer ML may cover a side surface of the first chip stack CS1, a side surface of the second chip stack CS2, the interconnection chip INC, and a side surface of the top semiconductor chip TC. In some example embodiments, an upper surface of the top semiconductor chip TC may be exposed from the mold layer ML.

Hereinafter, some components of the semiconductor package 10 will be described in more detail with reference to FIGS. 2A to 2D together with FIG. 1B.

FIG. 2A is a partially enlarged view of region “A” of FIG. 1A, and FIGS. 2B to 2D are example modifications of FIG. 2A. FIG. 2A illustrates some components of the semiconductor package 10, for example, a substrate 110, a circuit layer 120, through-vias TSV, and interconnection vias INV in more detail.

Referring to FIG. 2A, the substrate 110 may be a semiconductor wafer. The substrate 110 may include, for example, semiconductor elements such as silicon or germanium, or compound semiconductors such as silicon carbide (SiC), gallium arsenide (GaAs), indium arsenide (InAs), and indium phosphide (InP). The substrate 110 may include a conductive region 112 and an isolation region 111 formed on a front surface 110S1. The conductive region 112 may be, for example, a well doped with impurities or a structure doped with impurities. The isolation region 111, having device isolation structure having a shallow trench isolation (STI) structure, may include silicon oxide.

In one or more examples, the circuit layer 120 may be disposed on the front surface 110S1 of the substrate 110 on which the conductive region 112 is formed. The circuit layer 120 may include individual devices ID, an interlayer insulating layer 121, and a wire structure 125.

In one or more examples, the individual devices ID may be disposed on the front surface 110S1 of the substrate 110. The individual devices ID may include, for example, an FET such as a planar FET or a FinFET, a memory device such as flash memory, DRAM, SRAM, EEPROM, PRAM, MRAM, FeRAM, or RRAM, a logic device such as AND, OR, or NOT, and various active devices and/or passive devices such as a system LSI, a CIS, and an MEMS.

In one or more examples, the interlayer insulating layer 121 may be formed to cover the individual devices ID and the wire structure 125 to electrically isolate the individual devices ID, disposed on the substrate 110, from each other,. The interlayer insulating layer 121 may include flowable oxide (FOX), tonen silazene (TOSZ), undoped silica glass (USG), borosilica glass (BSG), phosphosilica glass (PSG), borophosphosilica glass (BPSG), plasma enhanced tetra ethyl ortho silicate (PETEOS), fluoride silicate glass (FSG), high-density plasma (HDP) oxide, plasma enhanced oxide (PEOX), flowable CVD (FCVD) oxide, or combinations thereof. At least a portion of the interlayer insulating layer 121, surrounding the wire structure 125, may include a low dielectric layer. The interlayer insulating layer 121 may be formed using a chemical vapor deposition (CVD) process, a flowable CVD process, or a spin coating process. Depending on the process, the interlayer insulating layer 121 and the lower insulating layer LI may not be clearly distinguished from each other.

The wire structure 125 may have a multilayer structure including a plurality of wire patterns and a plurality of vias formed of, for example, aluminum (Al), gold (Au), cobalt (Co), copper (Cu), nickel (Ni), lead (Pb), tantalum (Ta), tellurium (Te), titanium (Ti), tungsten (W), or combinations thereof. A barrier film including titanium (Ti), titanium nitride (TiN), tantalum (Ta), or tantalum nitride (TaN) may be disposed between the wire pattern or/and via and the interlayer insulating layer 121. The wire structure 125 may be electrically connected to the individual devices ID by an interconnector 123 (e.g., a contact plug).

In one or more examples, the lower pads LP may be electrically connected to the wire structure 125. The lower pads LP may include, for example, at least one of copper (Cu), nickel (Ni), gold (Au), silver (Ag), titanium (Ti), titanium nitride (TiN), tantalum (Ta), and tantalum nitride (TaN).

In one or more examples, the lower insulating layer LI may surround side surfaces of the lower pads LP. The lower insulating layer LI may include, for example, silicon oxide (SiO) or silicon carbonitride (SiCN). The lower insulating layer LI may form a bonding surface provided for inter-dielectric bonding between the lower pads LP.

In one or more examples, the upper pads UP may be electrically connected to the through-vias TSV. The upper pads UP may be electrically connected to the conductive region 112 and/or the wire structure 125 through the through-vias TSV.

In one or more examples, the upper insulating layer UI may surround side surfaces of the upper pads UP. The upper insulating layer UI may include, for example, silicon oxide (SiO) or silicon carbonitride (SiCN). The upper insulating layer UI may form a bonding surface provided for inter-dielectric bonding between the upper pads UP.

In one or more examples, the through-vias TSV may pass through the substrate 110 to electrically connect the lower pads LP and the upper pads UP to each other. The through-vias TSV may include a via plug 145, and a side barrier layer 141 surrounding a side surface thereof. The via plug 145 may include, for example, tungsten (W), titanium (Ti), aluminum (Al), or copper (Cu), and may be formed through a plating process, a PVD process, or a CVD process. The side barrier layer 141 may include titanium (Ti), titanium nitride (TiN), tantalum (Ta), or tantalum nitride (TaN), and may be formed using a plating process, a PVD process, or a CVD process. A side insulating film 143 including an insulating material such as silicon oxide, silicon nitride, or silicon oxynitride (for example, HARP oxide) may be formed between the side barrier layer 141 and the substrate 110.

In one or more examples, the through-vias TSV may pass through an insulating protective layer 113 formed on a rear surface 110S2 of the substrate 110. The insulating protective layer 113 may include, for example, silicon oxide (SiO), silicon nitride (SiN), silicon carbide (SiC), silicon oxynitride (SiON), or silicon carbonitride (SiCN). A buffer film 114, such as a polishing-stop layer or barrier, may be disposed on the insulating protective layer 113. For example, the buffer film may include silicon nitride, silicon carbide, silicon oxynitride, or silicon carbonitride.

The interconnection vias INV may pass through the chip body 210 to electrically connect, to each other, the first through-vias TSV1 of the top first semiconductor chip C1a and the second through-vias TSV2 of the bottom second semiconductor chip C2a. The interconnection vias INV may include the via plug 145 and the side barrier layer 141. The side insulating film 143 may be formed between the side barrier layer 141 and the chip body 210.

In an example embodiment, lower ends of the interconnection vias INV (e.g., first ends of the interconnection vias) of the interconnection chip INC may be in direct contact with the first upper pads UP1 of the top first semiconductor chip C1a, and upper ends of the interconnection vias INV (e.g., second ends of the interconnection vias) of the interconnection chip INC may be in direct contact with the second lower pads LP2 of the bottom second semiconductor chip C2a. The first upper insulating layer UI1 of the top first semiconductor chip C1a and the second lower insulating layer LI2 of the bottom second semiconductor chip C2a may be in contact with the chip body 210 of the interconnection chip INC. A horizontal width D of each of the interconnection vias INV may be on a level substantially the same as those of a horizontal width d1 of each of the first through-vias TSV1 and a horizontal width d2 of each of the second through-vias TSV2. In one or more examples, “the same level” may be based on a concept including a process error or margin of error, and may be understood as not being intentionally designed to be different. Thus, two surfaces that are at “the same level” may be substantially at the same level.

Referring to FIG. 2B, in a semiconductor package 10a according to a modification, interconnection vias INV may be formed to be larger than first through-vias TSV1 and second through-vias TSV2. A horizontal width D of each of the interconnection vias INV may be wider than a horizontal width d1 of each of the first through-vias TSV1 and a horizontal width d2 of each of the second through-vias TSV2. The interconnection vias INV provided for inter-metal bonding with first upper pads UP1 and second lower pads LP2 may have an increased area, and connection reliability and bonding quality may be improved.

Referring to FIGS. 2C and 2D, in semiconductor packages 10b and 10c according to modifications, an interconnection chip INC may further include bonding pads BDP, disposed on at least one of lower ends and upper ends of interconnection vias INV. A chip body 210 of the interconnection chip INC may include a semiconductor layer 210a, surrounding the interconnection vias INV, and a passivation layer 210b, surrounding the bonding pads BDP, on at least one surface of the semiconductor layer 210a.

The bonding pads BDP may be in contact with at least one of first upper pads UP1 of a top first semiconductor chip C1a, and second lower pads LP2 of a bottom second semiconductor chip C2a. A passivation layer 210b may be in contact with at least one of a first upper insulating layer UI1 of the top first semiconductor chip C1a and a second lower insulating layer LI2 of the bottom second semiconductor chip C2a. The first upper insulating layer UI1, the second lower insulating layer LI2, and the passivation layer 210b may include at least one of silicon oxide (SiO) and silicon carbonitride (SiCN), and the semiconductor layer 210a may include a semiconductor material such as silicon (Si) or germanium (Ge), but the present embodiments are not limited thereto. As such, the interconnection chip INC may further include any suitable components provided for inter-metal bonding and inter-dielectric bonding.

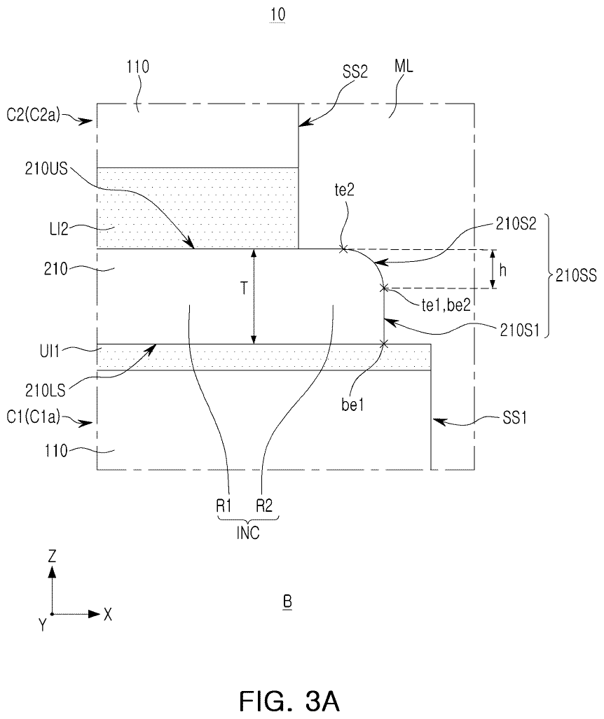

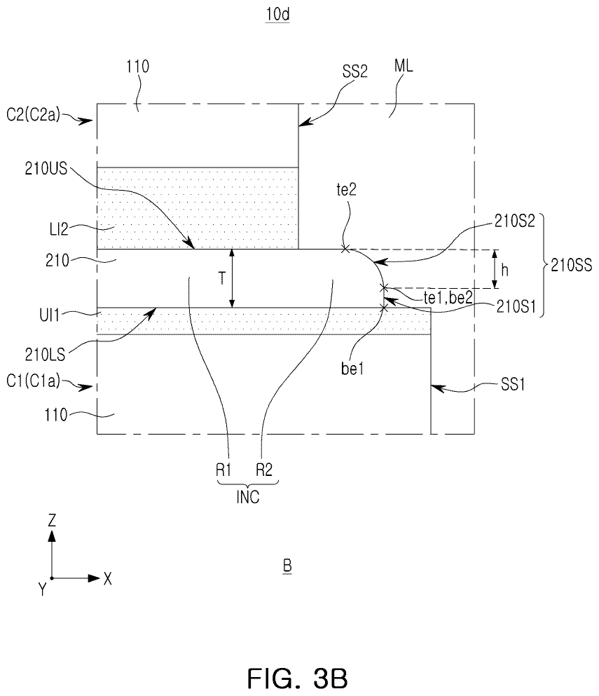

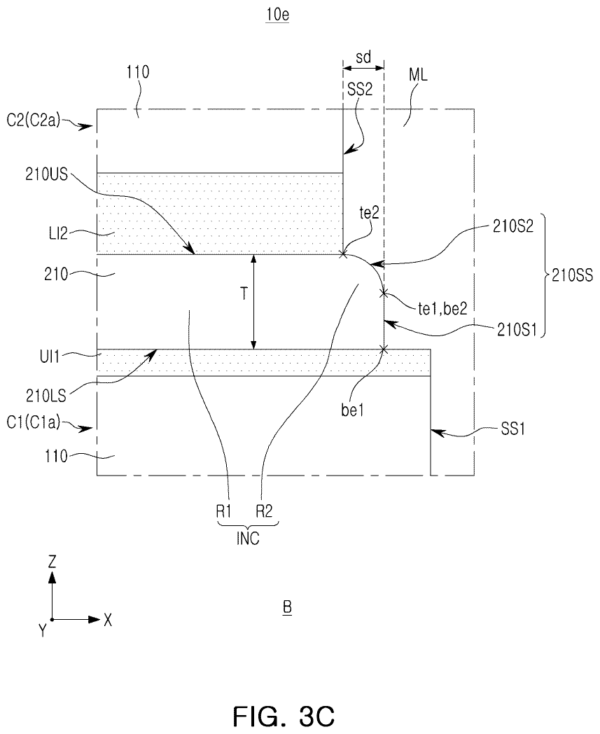

Hereinafter, referring to FIGS. 3A to 3C together with FIG. 1A and FIG. 1B, a shape of a side surface of the interconnection chip INC will be described in more detail.

FIG. 3A is a partially enlarged view of region “B” of FIG. 1B, and FIGS. 3B to 3C are example modifications of FIG. 3A.

Referring to FIG. 3A, the interconnection chip INC may have a lower surface 210LS (e.g., first surface) in contact with a first chip stack CS1, an upper surface 210US (e.g., second surface) in contact with a second chip stack CS2, and a side surface 210SS (e.g., third surface) between the lower surface 210LS and the upper surface 201US. The side surface 210SS of the interconnection chip INC may include a first portion 210S1 extending from the lower surface 210LS of the interconnection chip INC, and a second portion 210S2 extending from the first portion 210S1 to the upper surface 210US of the interconnection chip INC.

In one or more examples, the first portion 210S1 may extend at a constant inclination with respect to the lower surface 210LS of the interconnection chip INC. The second portion 210S2 may be formed using a planarization process, and thus, may extend at a constant or continuously changing inclination.

For example, the first portion 210S1 may have a first lower end bel (e.g., first end of first portion) connected to the lower surface 210LS of the interconnection chip INC, and a first upper end te1 (e.g., second end of first portion) connected to the second portion 210S2, and may extend at a constant first inclination from the first lower end bel to the first upper end te1. The second portion 210S2 may have a second lower end be2 (e.g., third end of second portion) connected to the first upper end te1, and a second upper end te2 (e.g., fourth end of second portion) connected to the upper surface 210US of the interconnection chip INC, and may extend at a second inclination decreasing from the second lower end be2 to the second upper end te2. For example, the second inclination of the second portion 210S2 may be lower than the first inclination of the first portion 210S1. For example, a height h of the second portion 210S2 may be less than or equal to ½ of a thickness T of the interconnection chip INC, but the present embodiments are not limited thereto.

In an example embodiment, the plurality of second semiconductor chips C2 may have a size (width and/or height) smaller than that of the interconnection chip INC so as to secure quality of a bonding surface and alignment margin. Accordingly, the side surface SS2 of the second chip stack CS2 may be spaced apart from the second upper end te2 of the second portion 210S2 in a horizontal direction (for example, an X-direction). In consideration of alignment margin between the plurality of second semiconductor chips C2, side surfaces of the plurality of second semiconductor chips C2, included in the side surface SS2 of the second chip stack CS2, may not form a flat vertical surface. For example, the side surface SS2 of the second chip stack CS2 is illustrated as a side surface of a bottom second semiconductor chip CS2a. However, in some example embodiments, side surfaces of second semiconductor chips C2 above the bottom second semiconductor chip CS2a, not positioned on a vertical surface the same as the side surface of the bottom second semiconductor chip CS2a, may also be spaced apart from the second upper end te2 of the second portion 210S2 in the horizontal direction (e.g., the X-direction).

In addition, the interconnection chip INC may include a first region R1 overlapping the second chip stack CS2 in a first direction (Z-direction), and a second region R2 extending from the first region R1 and overlapping the mold layer ML and the first chip stack CS1 in the first direction (Z-direction). A total length of a boundary line between the second region R2 of the interconnection chip INC and the mold layer ML in the first direction (Z-direction) may be greater than a thickness T of the interconnection chip INC in the first direction (Z-direction). In FIG. 3A, the total length of the boundary line between the second region R2 and the mold layer ML may be defined as a sum of a length of the first portion 210S1, a length of the second portion 210S2, and a length of a portion of the upper surface 210US in contact with the mold layer ML.

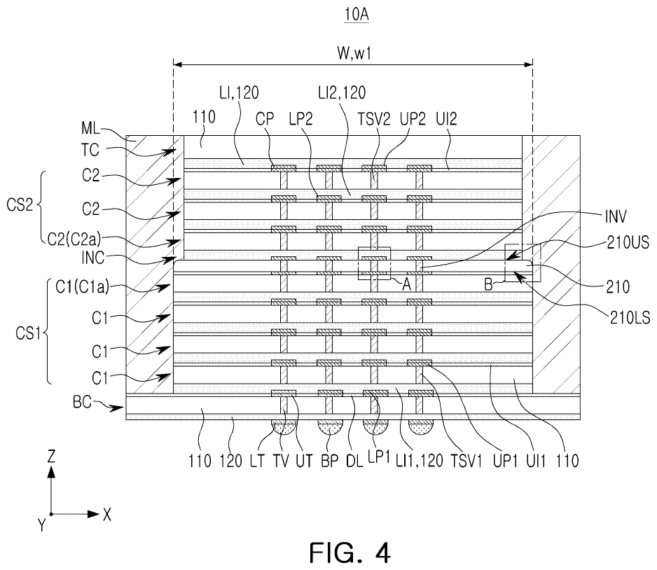

In an example embodiment, the interconnection chip INC may have a size (width and/or height) smaller than those of the plurality of first semiconductor chips C1 in consideration of alignment margin and stability of a planarization process. For example, the side surface 210SS (or the first portion 210S1) of the interconnection chip INC may be spaced apart from the side surface SS1 of the first chip stack CS1 in the horizontal direction (for example, the X-direction), but the present embodiments are not limited thereto (see the example embodiment of FIG. 4). In consideration of alignment margin between the plurality of first semiconductor chips C1, side surfaces of the plurality of first semiconductor chips C1, included in the side surface SS1 of the first chip stack CS1, may not form a flat vertical surface.

Referring to FIG. 3B, in a semiconductor package 10d according to a modification, a height h of a second portion 210S2 of a side surface 210SS of an interconnection chip INC may be greater than or equal to ½ of a thickness T of the interconnection chip INC. As such, the thickness T of the interconnection chip INC may be minimized to reduce a gap between a first chip stack CS1 and a second chip stack CS2, and to reduce the semiconductor package 10d in size and thickness. According to the modification, the side surface 210SS of the interconnection chip INC may not include a first portion 210S1 having a constant inclination.

Referring to FIG. 3C, in a semiconductor package 10e according to a modification, a second upper end te2 of a second portion 210S2 of a side surface 210SS of an interconnection chip INC may be aligned in a vertical direction (Z-direction). A plurality of second semiconductor chips C2 or a bottom second semiconductor chip C2a may have an area substantially equal to that of a flat upper surface 210US of the interconnection chip INC. In this case, in consideration of an edge portion of the interconnection chip INC having a curved surface and alignment margin, a separation distance (sd) between a side surface 210SS (or a first portion 210S1) of the interconnection chip INC and a side surface SS2 of a second chip stack CS2 may be about 1 μm or more, for example, in a range of about 1 μm to about 10 μm, about 1 μm to about 8 μm, or about 3 μm to about 8 μm, but the present embodiments are not limited thereto.

FIG. 4 is a cross-sectional view of a semiconductor package 10A according to an example embodiment.

Referring to FIG. 4, the semiconductor package 10A according to an example embodiment may have features the same as or similar to those described with reference to FIGS. 1A to 3C, except that a width W of an interconnection chip INC is substantially equal to a width w1 of a first chip stack CS. In example embodiments, a planarization process may be applied to the interconnection chip INC to remove surface topology accumulated by a plurality of first semiconductor chips C1. In order to ensure bonding stability between the interconnection chip INC and a top first semiconductor chip C1a during the planarization process, the interconnection chip INC may have at least an area substantially equal to an area of the top first semiconductor chip C1a. However, in consideration of alignment margin of the interconnection chip INC and the top first semiconductor chip C1a, a side surface of the interconnection chip INC and a side surface of the top first semiconductor chip C1a may form the same vertical surface.

FIG. 5 is a cross-sectional view of a semiconductor package 10B according to an example embodiment.

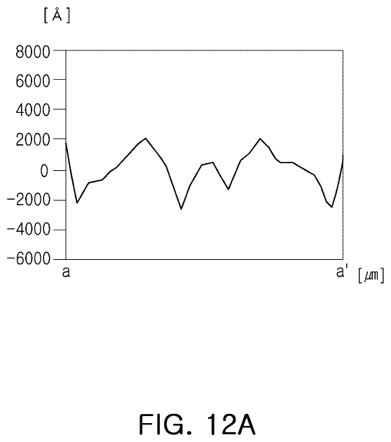

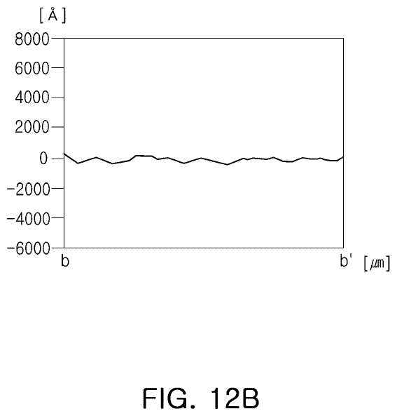

Referring to FIG. 5, the semiconductor package 10B according to an example embodiment may have features the same as or similar to those described with reference to FIGS. 1A to 4, except that the number (e.g., eight) of first semiconductor chips C1, included in a first chip stack CS1, is greater than the number (e.g., four) of a top semiconductor chip TC (e.g., third semiconductor) added to a second chip stack CS2. In example embodiments, after the maximum number of first semiconductor chips C1 are stacked, the interconnection chip INC may be disposed on the uppermost first semiconductor chip C1a having surface topology that is accumulated such that bonding quality of a bonding surface is degraded. For example, the number of first semiconductor chips C1 included in the first chip stack CS1 is not particularly limited. Surface topology properties of the top first semiconductor chip C1a on which the interconnection chip INC is disposed will be described below with reference to FIGS. 12A and 12B.

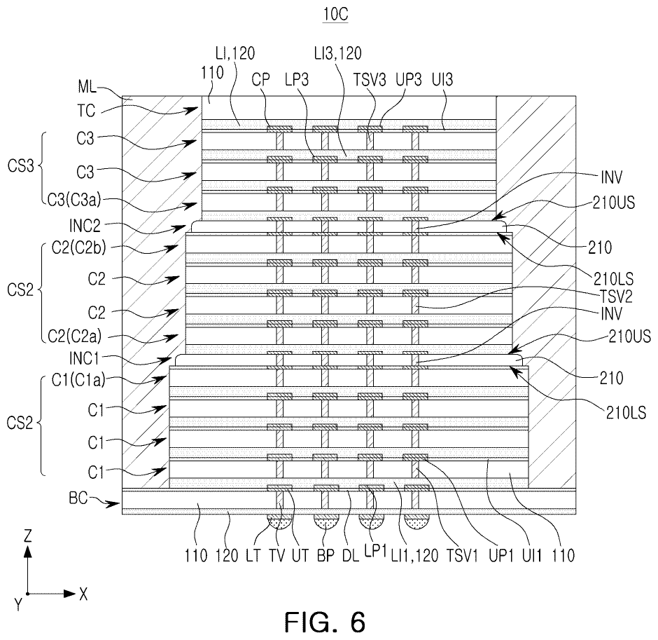

FIG. 6 is a cross-sectional view of a semiconductor package 10C according to an example embodiment.

Referring to FIG. 6, the semiconductor package 10C according to the example embodiment may have the same or similar features as those described with reference to FIGS. 1A to 5, except that a plurality of interconnection chips INC1 and INC2 are included. In some example embodiments, the number of the plurality of interconnection chips INC1 and INC2 and a plurality of chip stacks CS1, CS2, and CS3 stacked may be greater the number of those illustrated in the drawing.

In one or more examples, the semiconductor package 10C may include a base chip BC, a first chip stack CS1, a second chip stack CS2, a third chip stack CS3, a top semiconductor chip TC, and a first interconnection chip INC1, and a second interconnection chip INC2. The base chip BC, the first chip stack CS1, the second chip stack CS2, and the first interconnection chip INC1 may have features the same as those of the above-described base chip BC, first chip stack CS1, second chip stack CS2, and interconnection chip INC, and thus a repeated description will be omitted below.

In one or more example embodiments, the second interconnection chip INC2 may be disposed on a top second semiconductor chip C2b, among a plurality of second semiconductor chips C2. The second interconnection chip INC2 may remove surface topology accumulated by the plurality of second semiconductor chips C2, and may improve bonding quality and reliability of the third chip stack CS3. The second interconnection chip INC2 may have a lower surface 210LS in contact with the top second semiconductor chip C2b, and an upper surface 210US in contact with a bottom third semiconductor chip C3a. The lower surface 210LS of the second interconnection chip INC2 may be a wave surface on which the plurality of second semiconductor chips C2 have the accumulated surface topology. In one or more examples, the upper surface 210US of the second interconnection chip INC2 may be a flat surface to which a planarization process has been applied. The second interconnection chip INC2 may have features substantially the same as those of the above-described interconnection chip INC, and thus a description thereof may be replaced with the description related to FIGS. 1A to 3C.

The third chip stack CS3 may include a plurality of third semiconductor chips C3 stacked on the second interconnection chip INC2 in a first direction (Z-direction). In some example embodiments, the number of third semiconductor chips C3 may be greater or less than the number of those illustrated in the drawing. The third chip stack CS3 may have a width narrower than a horizontal width of the second interconnection chip INC2.

The plurality of third semiconductor chips C3 may include third lower pads LP3 and third upper pads UP3 opposite to each other, and third through-vias TSV3. The third through-vias TSV3 may be electrically connected to second through-vias TSV2 in the first direction (Z-direction) and electrically connected to each other in the first direction (Z-direction). The top semiconductor chip TC may include connection pads CP electrically connected to third through-vias TSV3 of a top third semiconductor chip C3.

In one or more examples, each of the plurality of third semiconductor chips C3 may include a third lower insulating layer LI2 surrounding the third lower pads LP3, and a third upper insulating layer UI3 surrounding the third upper pads UP3. The third upper insulating layer UI3 of each of the plurality of third semiconductor chips C3 may be in contact with a third lower insulating layer LI3 of each of the plurality of third semiconductor chips C3 adjacent thereto in the first direction (Z-direction). The third upper pads UP3 of each of the plurality of third semiconductor chips C3 may be in contact with the third lower pads LP3 of each of the plurality of third semiconductor chips C3 adjacent thereto in the first direction (Z-direction).

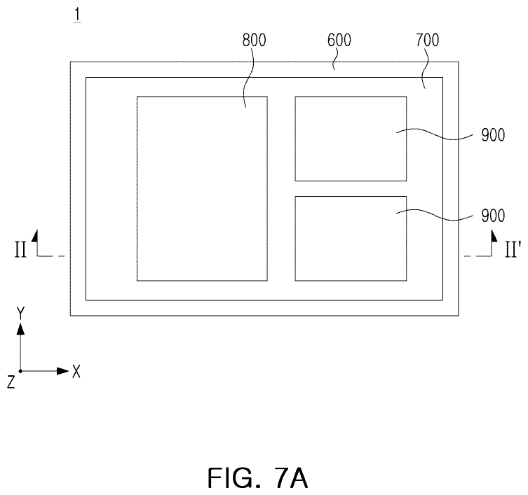

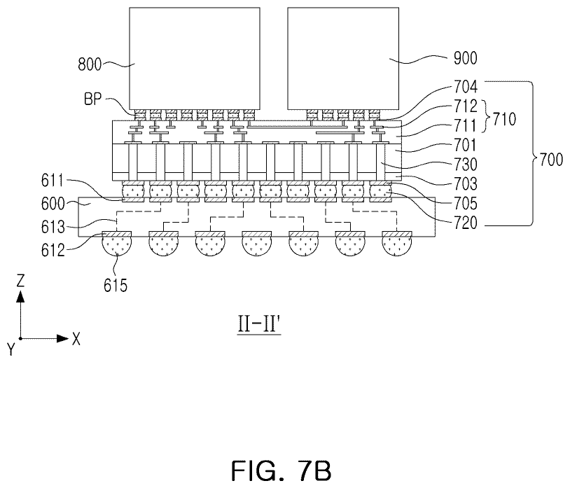

FIG. 7A is a plan view of a semiconductor package 1 according to an example embodiment of the present embodiments, and FIG. 7B is a cross-sectional view taken along line II-II′ of FIG. 7A.

Referring to FIGS. 7A and 7B, the semiconductor package 1 according to an example embodiment may include a package substrate 600, an interposer substrate 700, a first chip structure 800, and a second chip structure 900.

The first chip structure 800 may include a logic chip such as a central processor (CPU), a graphics processing unit (GPU), a field-programmable gate array (FPGA), a digital signal processor, an encryption processor, a microprocessor, a microcontroller, an analog-digital converter, or an application-specific IC (ASIC).

The second chip structure 900 may be understood as a semiconductor package structure having features the same as or similar to those of the semiconductor packages 10, 10a, 10b, 10c, 10d, 10e, 10A, 10B, and 10C described with reference to FIGS. 1A to 6. For example, the second chip structure 900 may include a high-capacity memory device such as a high-bandwidth memory (HBM).

In one or more examples, the package substrate 600 may be a support substrate on which the interposer substrate 700 is mounted, and may be a substrate for a semiconductor package including a printed circuit board (PCB), a ceramic substrate, a glass substrate, a tape wire substrate, or the like. The package substrate 600 may include a lower pad 612, an upper pad 611, and a wire circuit 613. An external connection bump 615, connected to the lower pad 612, may be disposed on a lower surface of the package substrate 600. The external connection bump 615 may include, for example, a solder ball.

The interposer substrate 700 may include a semiconductor substrate 701, a lower protective layer 703, a lower pad 705, an interconnection structure 710, a conductive bump 720, and a through-silicon via 730. The first chip structure 800 and the second chip structure 900 may be electrically connected to each other through the interposer substrate 700.

The semiconductor substrate 701 may be formed of, for example, one of silicon, organic, plastic, and glass substrates. When the semiconductor substrate 701 is a silicon substrate, the interposer substrate 700 may be referred to as a silicon interposer. Unlike that illustrated in the drawing, when the semiconductor substrate 701 is an organic substrate, the interposer substrate 700 may be referred to as a panel interposer.

In one or more examples, the lower protective layer 703 may be disposed on a lower surface of the semiconductor substrate 701, and the lower pad 705 may be disposed below the lower protective layer 703. The lower pad 705 may be connected to the through-silicon via 730. The interposer substrate 700 may be electrically connected to the package substrate 600 through conductive bumps 720 disposed below the lower pad 705.

In one or more examples, the interconnection structure 710 may be disposed on an upper surface of the semiconductor substrate 701, and may include an interlayer insulating layer 711 and a single-layer or multilayer wire structure 712. When the interconnection structure 710 has a multilayer wire structure, wire patterns of different layers may be connected to each other through a contact via. The first semiconductor chip structure 800 and the second semiconductor chip structure 900 may be electrically connected to an upper pad 704 through the connection bumps BP.

In one or more examples, the through-silicon via 730 may extend from an upper surface to a lower surface of the semiconductor substrate 701. In addition, the through-silicon via 730 may extend into the interconnection structure 710 to be electrically connected to the multilayer wire structure 712. In some example embodiments, the interposer substrate 700 may include only an interconnection structure therein, and may not include the through-silicon via 730.

In one or more examples, the interposer substrate 700 may be used to convert or transmit an input electrical signal between the package substrate 600 and the first semiconductor chip structure 800 or the second semiconductor chip structure 900. Accordingly, the interposer substrate 700 may not include devices such as active devices or passive devices. In addition, in some example embodiments, the interconnection structure 710 may be disposed on a lower portion of the through-silicon via 730. For example, the interconnection structure 710 and the through-silicon via 730 may have a relative positional relationship therebetween.

FIGS. 8A to 11B are diagrams illustrating a process of manufacturing a semiconductor package according to an example embodiment.

Referring to FIGS. 8A and 8B, first chip stacks CS1 including a plurality of first semiconductor chips C1 may be formed on a semiconductor wafer WF. The semiconductor wafer WF may include preliminary base chips BC′ separated by scribe lanes SL. The plurality of first semiconductor chips C1 may be stacked in a vertical direction (Z-direction). The plurality of first semiconductor chips C1 may be bonded to each other using a thermal compression process. The plurality of first semiconductor chips C1 may be directly bonded to each other by inter-metal bonding and inter-dielectric bonding (hereinafter referred to as “direct bonding”), without a conductive member (e.g., a solder bump, a copper pillar, or the like) for electrical connection. It may be understood that a plurality of base chips BC and the plurality of first semiconductor chips C1 include the components described with reference to FIGS. 1A to 2A. Upper and lower surfaces of each of the plurality of first semiconductor chips C1 may be directly bonded to each other, such that surface topology properties of an upper surface US of a top first semiconductor chip C1a having accumulated surface topology may be degraded.

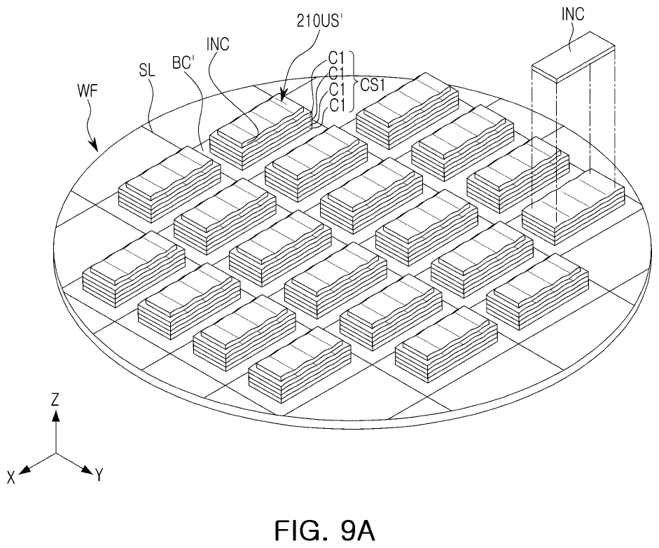

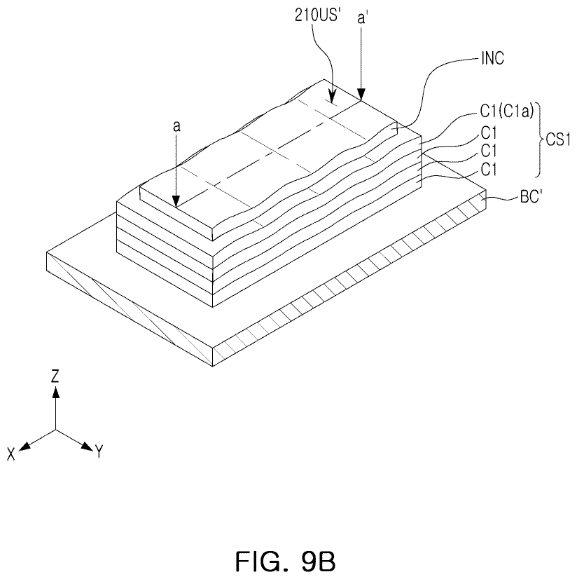

Referring to FIGS. 9A and 9B, interconnection chips INC may be attached to the first chip stacks CS1, respectively. The interconnection chips INC may be bonded to the top first semiconductor chip C1a using the thermal compression process. The interconnection chips INC may be directly bonded to the top first semiconductor chip C1a, and thus, temporary upper surfaces 210U′ of the interconnection chips INC may have surface topology corresponding to the top first semiconductor chip C1a. The interconnection chips INC may have a size (width and/or height) smaller than those of the plurality of first semiconductor chips C1 in consideration of alignment margin and stability of the planarization process, but the present embodiments are not limited thereto. The surface topology of the top first semiconductor chip C1a and the interconnection chips INC is illustrated in an example unidirectional wave form for ease of description.

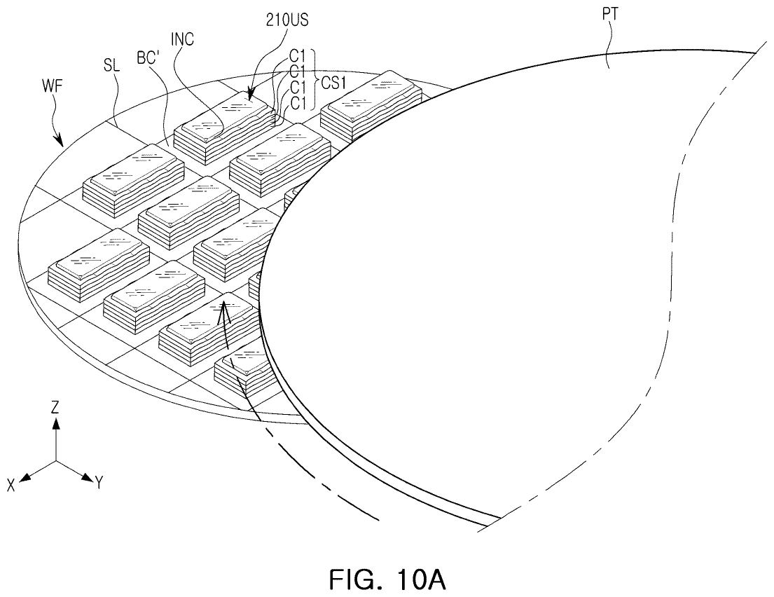

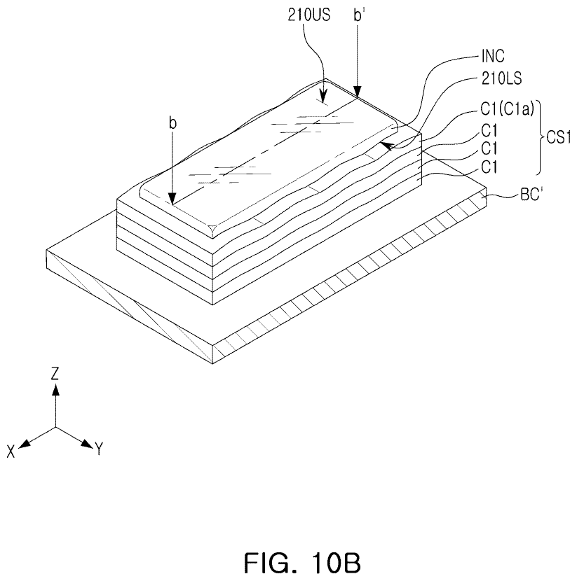

Referring to FIGS. 10A and 10B, a planarization process may be applied to interconnection chips INC. The planarization process may include a grinding process and a polishing process. For example, a portion of an upper portion of each of the interconnection chips INC may be removed using a planarization equipment (PT) such as a grinding wheel or polishing pad, thereby forming a flat surface provided for “direct bonding.” Accordingly, a lower surface 210LS of each of the interconnection chips INC may be a wave surface with varying heights (or multiple raised portions), and an upper surface 210US of each of the interconnection chips INC may be a flat surface. The upper surface 210US of the interconnection chip INC may be polished to have a surface roughness (Ra) of about 0.05 nm or less, for example, in a range of about 0.01 nm to about 0.05 nm. The lower surface 210LS of the interconnection chip INC, directly bonded to a top first semiconductor chip C1a, may also have a surface roughness (Ra) of about 0.05 nm or less. A portion of a side surface of each of the planarized interconnection chips INC may be a curved surface having a constantly changing inclination (see FIG. 3A or the like).

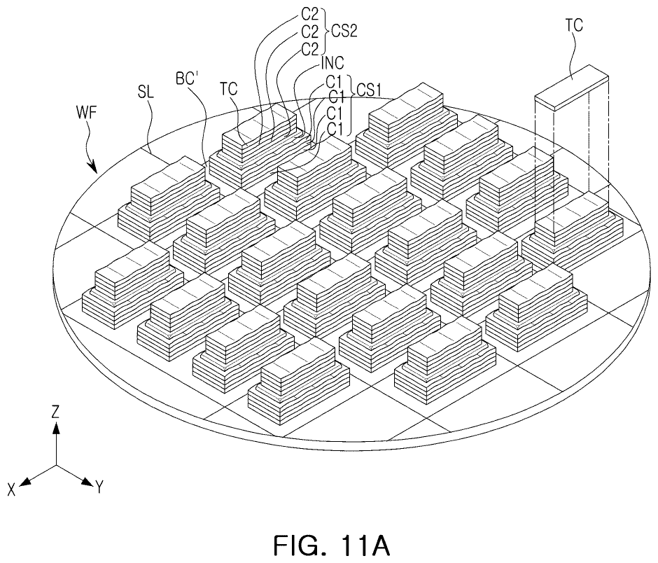

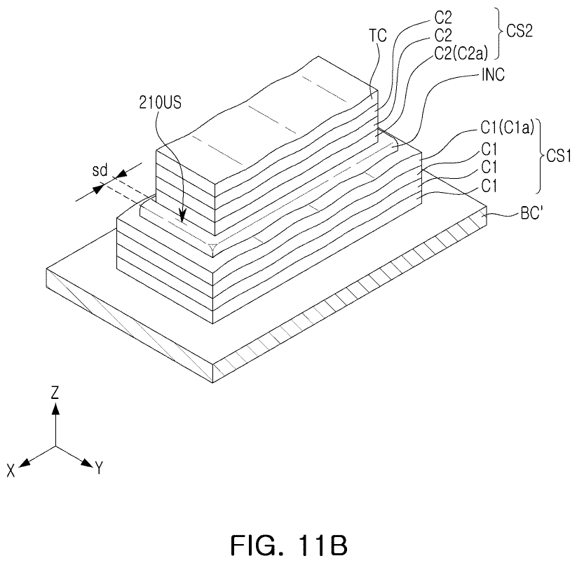

Referring to FIGS. 11A and 11B, second chip stacks CS2 including a plurality of second semiconductor chips C2 may be formed on the planarized interconnection chips INC, and a top semiconductor chip TC may be attached. The plurality of second semiconductor chips C2 may be stacked on the interconnection chip INC in a vertical direction (Z-direction). The plurality of second semiconductor chips C2 may be directly bonded to each other using a thermal compression process, without a conductive member (e.g., a solder bump, a copper pillar, or the like). It may be understood that the plurality of second semiconductor chips C2 include the components described with reference to FIGS. 1A to 2A.

The plurality of second semiconductor chips C2 may be stacked on an upper surface 210US of the planarized interconnection chip INC, such that a second chip stack CS2 having excellent bonding quality may be formed between the plurality of second semiconductor chips C2. In order to secure quality and alignment margin of a bonding surface, the plurality of second semiconductor chips C2 may have a size (width and/or height) smaller than that of the interconnection chip INC. A horizontal width (X-direction and Y-direction) of each of the second chip stacks CS2 may be narrower than a horizontal width of each of the corresponding interconnection chips INC. In consideration of an edge portion of the interconnection chip INC having a curved surface and alignment margin, a separation distance (sd) between a side surface of the interconnection chip INC and a side surface of the second chip stack CS2 may be about 1 μm or more, for example, in a range of about 1 μm to about 10 μm, about 1 μm to about 8 μm, or about 3 μm to about 8 μm, but the present embodiments are not limited thereto.

Thereafter, a mold layer, exposing the top semiconductor chip TC, may be formed on a semiconductor wafer WF, and a cutting process may be performed along a scribe lane SL to isolate individual semiconductor packages from each other.

FIGS. 12A and 12B are graphs illustrating surface topology of an interconnection chip before and after a planarization process is performed. FIGS. 12A and 12B illustrate results of scanning surface topology of an interconnection chip INC before and after a planarization process is performed using an atomic force microscope (AFM). FIG. 12A illustrates surface topology in a range a-a′ of FIG. 9b, and FIG. 12b illustrates surface topology in a range b-b′ of FIG. 10B.

Referring to FIGS. 12A and 12B, a temporary upper surface 210US′ of the interconnection chip INC before the planarization process is performed may have topology properties having a large height difference in surface curvature. For example, a difference between a highest point and a lowest point of the temporary upper surface 210 US' may be about 4,000 Å or more. An inclination of a surface curvature of the temporary top surface 210US′ may be about 3 Å/μm or more. However, the above-described numeral values may be example numerical values defining surface topology properties in which bonding quality of direct bonding may be degraded, and example embodiments of the present embodiments are not applicable only to the above-described numerical range.

After the planarization process is performed, an upper surface 210US of the interconnection chip INC may be a flat surface with a surface curvature removed. Accordingly, a difference between a highest point and a lowest point of the upper surface 210US of the interconnection chip INC may be about 10 Å or less, and an inclination of the surface curvature may be about 0.1 Å/μm or less. However, the above-described numeral values may be exemplary numeral values, and the difference between the highest point and lowest point of the upper surface 210US of the interconnection chip INC and the inclination of the surface curvature may be substantially close to 0.

According to example embodiments of the present embodiments, a planarized interconnection chip may be inserted between a plurality of semiconductor chips stacked in multiple stages, thereby providing a semiconductor package having improved bonding surface quality and reliability.

While example embodiments have been shown and described above, it will be apparent to those skilled in the art that modifications and variations could be made without departing from the scope of the present embodiments as defined by the appended claims.

1. A semiconductor package comprising:
a base chip comprising first connection terminals and second connection terminals opposite to each other, and through-electrodes electrically connecting the first connection terminals and the second connection terminals to each other;
a first chip stack stacked on the base chip in a first direction, the first chip stack comprising a plurality of first semiconductor chips comprising a first set of pads and a second set of pads, opposite to each other, and first through-vias electrically connecting the first set of pads and the second set of pads to each other;
a second chip stack stacked on the first chip stack in the first direction, the second chip stack comprising a plurality of second semiconductor chips comprising a third set of pads and a fourth set of pads, opposite to each other, and second through-vias electrically connecting the third set of pads and the fourth set of pads to each other;
an interconnection chip between the first chip stack and the second chip stack, the interconnection chip comprising interconnection vias electrically connecting the first through-vias and the second through-vias to each other;
a mold layer covering at least a portion of each of the first chip stack, the second chip stack, and the interconnection chip, on the base chip; and
a plurality of connection bumps below the base chip, the plurality of connection bumps electrically connected to the first connection terminals,
wherein the first set of pads of each of the plurality of first semiconductor chips are in contact with the second connection terminals of the base chip adjacent thereto in the first direction, and the second set of pads of each of the plurality of first semiconductor chips adjacent thereto in the first direction,
the fourth set of pads of each of the plurality of second semiconductor chips are in contact with the third set of pads of each of the plurality of second semiconductor chips adjacent thereto in the first direction,
the interconnection chip has a first surface in contact with the first chip stack, a second surface in contact with the second chip stack, and a third surface between the first surface and the second surface, and
the third surface of the interconnection chip comprises a first portion extending from the first surface of the interconnection chip at a first inclination, and a second portion extending from the first portion to the second surface of the interconnection chip at a second inclination lower than the first inclination.

2. The semiconductor package of claim 1, wherein
the first portion has a first end connected to the first surface of the interconnection chip, and a second end connected to the second portion, and
the first inclination is constant from the first end to the second end.

3. The semiconductor package of claim 2, wherein
the second portion has a third end connected to the second end of the first portion, and a fourth end connected to the second surface of the interconnection chip, and
the second inclination decreases from the third end to the fourth end.

4. The semiconductor package of claim 3, wherein a surface of the second chip stack extending in the first direction is spaced apart from the fourth end of the second portion.

5. The semiconductor package of claim 1, wherein a thickness from the first surface to the second surface of the interconnection chip is less than a thickness of a first semiconductor chip adjacent in the first direction among the plurality of first semiconductor chips, and a thickness of a second semiconductor chip adjacent in the first direction among the plurality of second semiconductor chips.

6. The semiconductor package of claim 5, wherein the thickness of the interconnection chip is about 30 μm or less.

7. The semiconductor package of claim 1, wherein a first width of the first chip stack in a second direction, perpendicular to the first direction, is wider than a second width of the second chip stack in the second direction.

8. The semiconductor package of claim 7, wherein a width of the interconnection chip in the second direction is equal to or narrower than the first width of the first chip, and is wider than the second width.

9. The semiconductor package of claim 8, wherein a third width of the base chip in the second direction is wider than the first width.

10. The semiconductor package of claim 1, further comprising:
a third semiconductor chip on the second chip stack, the third semiconductor chip comprising connection pads electrically connected to the second through-vias.

11. The semiconductor package of claim 1, wherein
each of the plurality of first semiconductor chips further includes a first insulating layer surrounding the first set of pads, and a second insulating layer surrounding the second set of pads,
each of the plurality of second semiconductor chips further includes a third insulating layer surrounding the third set of pads, and a fourth insulating layer surrounding the fourth set of pads,
the interconnection chip further includes a chip body surrounding the interconnection vias, the chip body defining the first surface of the interconnection chip and the second surface of the interconnection chip, and
the second insulating layer of a first semiconductor chip adjacent to the interconnection chip in the first direction, among the plurality of first semiconductor chips, and the third insulating layer of a second semiconductor chip adjacent to the interconnection chip in the first direction, among the plurality of second semiconductor chips, are in contact with the chip body of the interconnection chip.

12. The semiconductor package of claim 11, wherein
the first insulating layer, the second insulating layer, the third insulating layer, and the fourth insulating layer include at least one of silicon oxide (SiO) and silicon carbonitride (SiCN), and
the chip body includes silicon (Si).

13. The semiconductor package of claim 11, wherein
first ends of the interconnection vias of the interconnection chip are in contact with the second set of pads of the first semiconductor chip, and
second ends of the interconnection vias of the interconnection chip are in contact with the third set of pads of the second semiconductor chip.

14. The semiconductor package of claim 11, wherein
the interconnection chip further includes bonding pads disposed on at least one of first ends and second ends of the interconnection vias,
the chip body of the interconnection chip further includes a semiconductor layer surrounding the interconnection vias, and a passivation layer surrounding the bonding pads on at least one surface of the semiconductor layer,
the bonding pads are in contact with at least one of the second set pads of the first semiconductor chip and the third set of pads of the second semiconductor chip, and
the passivation layer is in contact with at least one of the second insulating layer of the first semiconductor chip and the third insulating layer of the second semiconductor chip.

15. The semiconductor package of claim 14, wherein
the first insulating layer, the second insulating layer, the third insulating layer, the fourth insulating layer, and the passivation layer include at least one of silicon oxide (SiO) and silicon carbonitride (SiCN), and
the semiconductor layer of the chip body includes silicon (Si).

16. The semiconductor package of claim 11, wherein
the base chip further includes a dielectric layer surrounding the second connection terminals,
the first insulating layer of each of the plurality of first semiconductor chips is in contact with the dielectric layer of the base chip adjacent thereto in the first direction, and the second insulating layer of each of the plurality of first semiconductor chips adjacent thereto in the first direction, and
the fourth insulating layer of each of the plurality of second semiconductor chips is in contact with the third insulating layer of each of the plurality of second semiconductor chips adjacent thereto in the first direction.

17. A semiconductor package comprising:
a base chip comprising through-electrodes;
a first chip stack stacked on the base chip in a first direction, the first chip stack comprising a plurality of first semiconductor chips comprising first through-vias electrically connected to the through-electrodes in the first direction, the first through-vias electrically connected to each other in the first direction;
a second chip stack stacked on the first chip stack in the first direction, the second chip stack comprising a plurality of second semiconductor chips comprising second through-vias electrically connected to each other in the first direction;
an interconnection chip between the first chip stack and the second chip stack, the interconnection chip comprising interconnection vias electrically connecting the first through-vias and the second through-vias to each other; and
a mold layer covering a surface of the first chip stack extending in the first direction, a surface of the second chip stack extending in the first direction, and a surface of the interconnection chip extending in the first direction,
wherein the interconnection chip includes a first region overlapping the second chip stack in the first direction, and a second region extending from the first region and overlapping the mold layer and the first chip stack in the first direction.

18. The semiconductor package of claim 17, wherein a total length of a boundary line between the second region of the interconnection chip and the mold layer is greater than a thickness of the interconnection chip in the first direction.

19. A semiconductor package comprising:
a base chip comprising through-electrodes;
a plurality of first semiconductor chips stacked on the base chip in a first direction, the plurality of first semiconductor chips comprising first through-vias electrically connected to the through-electrodes in the first direction, the first through-vias electrically connected to each other in the first direction;
a plurality of second semiconductor chips stacked on the plurality of first semiconductor chips in the first direction, the plurality of second semiconductor chips comprising second through-vias electrically connected to each other in the first direction; and
an interconnection chip between a top first semiconductor chip among the plurality of first semiconductor chips, and a bottom second semiconductor chip among the plurality of second semiconductor chips, the interconnection chip comprising interconnection vias electrically connecting the first through-vias and the second through-vias to each other,
wherein a thickness of the interconnection chip in the first direction is less than a thickness of each of the plurality of first semiconductor chips and a thickness of each of the plurality of second semiconductor chips,
the interconnection chip has a first surface in contact with the top first semiconductor chip, and a second surface in contact with the bottom second semiconductor chip,
the first surface of the interconnection chip is a wave surface having varying heights, and
the second surface of the interconnection chip is a flat surface.

20. The semiconductor package of claim 19, wherein a surface roughness of each of the first surface and the second surface of the interconnection chip is about 0.05 nm or less.

21-25. (canceled)
